(19) United States
(12) Patent Application Publication
(10) Pub. No.: US 2010/0070211 A1
(43) Pub. Date: Mar. 18, 2010

(54) ROLLING AVERAGE TEST

(75) Inventors: Brian Surette, Hudson, NH (US); Thomas W. Kelly, Ipswich, MA (US); James E. Martin, Hudson, NH (US); Bernard Tan, Medford, MA (US)

Correspondence Address: KENYON & KENYON LLP, 1500 K STREET, NW, WASHINGTON, DC, 20005-1257, US

(73) Assignee: ANALOG DEVICES, INC., Norwood, MA (US)

(21) Appl. No.: 12/210,090

(22) Filed: Sep. 12, 2008

(51) Int. Cl. G01R 31/26

(52) U.S. Cl. 702/58

(57) ABSTRACT

A system and method for performing dynamic in-line testing of semiconductor devices sequentially tests a plurality of semiconductor devices. Test data associated with a predetermined number of semiconductor devices of the sequentially tested semiconductor devices is stored in a data structure. After test data corresponding to a predetermined number of semiconductor devices is stored in the data structure, the following steps are iteratively performed. Statistics concerning the selected devices are calculated using the associated test data. A device that fails to meet a precision setting based on the statistics is marked as an outlier device. Test data stored in the data structure corresponding to an earliest tested semiconductor device in sequence is evicted from the data structure. Test data associated with the next passing tested semiconductor device in sequence is stored in the data structure.

### BACKGROUND

1. Field of the Invention

Aspects of the present invention relate generally to testing and evaluation of semiconductor devices, and more particularly to a system and method of removing statistical outliers during semiconductor production testing.

2. Description of Related Art

Fabrication of semiconductor devices will invariably yield a percentage of devices that do not conform to specified standards. When testing for statistical outliers, devices that are significantly distant from a test mean, test limits for production testing of integrated circuits require a margin for process variation to determine specifications that can be supported over time with acceptable yields. Outliers have the potential to behave as unstable devices. These outlier devices should be removed from a production lot during a validation process to prevent their incorporation and use in a finished product or component.

In addition to known electrical validation tests for semiconductor devices, post-electrical tests exist to identify devices that fail to meet specified standards. These tests generally are static tests that use historical data and generate a historical mean and other statistics to remove outlier devices. These static tests do not necessarily identify outlier devices accurately due to the fact that local distributions can move around in a production lot. One post-electrical test called Adaptive Limits may perform a random sampling of a predetermined number of devices from a production lot and generate statistical data from the sampling. Adaptive Limits suffers from problems, however, including that the test is time consuming and not necessarily precise in identifying outlier devices.

Therefore, it may be desirable to provide a system and method that performs dynamic, in-line testing of semiconductor devices to precisely identify outlier devices that fail to meet specified standards.

### SUMMARY

Embodiments of the present invention overcome the above-mentioned and various other shortcomings of conventional technology, providing a system and method for performing dynamic in-line testing of semiconductor devices. A plurality of semiconductor devices may be sequentially tested. Test data associated with a predetermined number of semiconductor devices of the sequential tested semiconductor devices may be stored in a data structure. After test data for the predetermined number of semiconductor devices is stored in the data structure, the method may iteratively perform the following steps. Statistics concerning the predetermined number of semiconductor devices may be calculated using the associated test data. A device that fails to meet a precision setting based on the statistics may be marked as an outlier device. Test data stored in the data structure corresponding to an earliest tested semiconductor device in sequence may be evicted from the data structure. Test data associated with the next passing tested semiconductor device in sequence may be stored in the data structure.

The foregoing and other aspects of various embodiments of the present invention will be apparent through examination of the following detailed description thereof in conjunction with the accompanying drawing figures.

### BRIEF DESCRIPTION OF THE DRAWING FIGURES

FIG. 1 illustrates a possible configuration of a computer system to implement the application components under the present invention.

FIG. 2 is a graph of one embodiment of a static test process.

FIG. 3 illustrates in a flowchart an embodiment for implementing a dynamic in-line testing algorithm.

FIG. 4 illustrates in a flowchart an embodiment for implementing a dynamic in-line testing algorithm.

FIG. 5 illustrates in a flowchart an embodiment for implementing a dynamic in-line testing algorithm.

FIG. 6 illustrates a graph of an embodiment of a dynamic in-line testing algorithm.

### DETAILED DESCRIPTION

It will be appreciated from the following description that the embodiments set forth herein may have utility in connection with testing semiconductor devices including but not limited to individual semiconductor devices, integrated circuits, and dies, in a variety of fields, including but not limited to automotive, medical, cellular telephony, and radio frequency component applications.

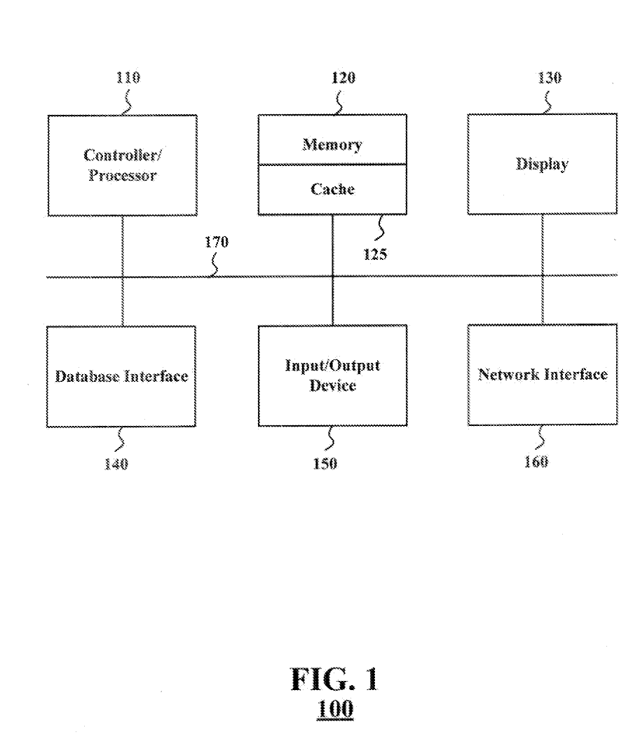

FIG. 1 illustrates a possible configuration of a computer system 100 to implement application components under the present invention. The type of computer system that may implement the present invention is not intended to be limiting. The computer system 100 may include a controller/processor 110, a memory 120 with a cache 125, display 130, database interface 140, input/output device interface 150, and network interface 160, connected through bus 170.

The controller/processor 110 may be any programmed processor known to one of skill in the art. However, the rolling average test (“RAT”) method can also be implemented on a general-purpose or a special purpose computer, a programmed microprocessor or microcontroller, peripheral integrated circuit elements, an application-specific integrated circuit or other integrated circuits, hardware/electronic logic circuits, such as a discrete element circuit, a programmable logic device, such as a programmable logic array, field programmable gate-array, or the like. In general, any device or devices capable of implementing the RAT method as described herein can be used to implement the decision support system functions of this invention.

The memory 120 may include volatile and nonvolatile data storage, including one or more electrical, magnetic or optical memories such as a RAM, cache, hard drive, CD-ROM drive, tape drive or removable storage disk, or any computer-readable storage medium. The memory may have a cache 125 to speed access to specific data.

The Input/Output interface 150 may be connected to one or more input devices that may include a keyboard, mouse, pen-operated touch screen or monitor, voice-recognition device, or any other device that accepts input. The Input/Output interface 150 may also be connected to one or more output devices, such as a monitor, printer, disk drive, speakers, or any other device provided to output data.

The network interface 160 may be connected to a communication device, modem, network interface card, a transceiver, or any other device capable of transmitting and receiving signals over a network. The components of the computer system 100 may be connected via an electrical bus 170, for example, or linked wirelessly.

Client software and databases may be accessed by the controller/processor 110 from memory 120 or through the database interface 140, and may include, for example, database applications, testing applications, word processing applications, as well as components that embody the RAT functionality of the present invention. The computer system 100 may implement any operating system, such as Windows or UNIX, for example. Client and server software may be written in any programming language, including but not limited to C, C++, Java or Visual Basic, for example.

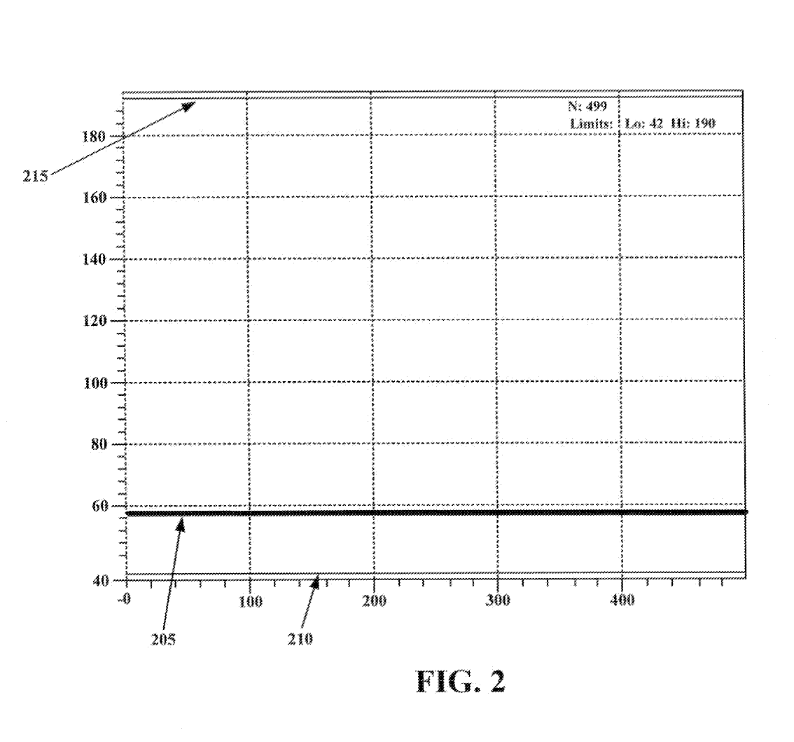

By way of illustration, FIG. 2 is a graph of one embodiment of a static test process. A static test process selects a predetermined number of parts within a single lot and generates statistics based on the sampling. The selection of parts or devices may be random. The parts within the lot are compared to the statistics and either approved or flagged as outliers. Data points corresponding to device test data are displayed collectively as element 205. Testing boundaries 210, 215 may represent device specifications. Because of the wide testing boundaries 210, 215 in the embodiment shown in FIG. 2, the data points 205 may not be individually distinguishable in the graph. As can be seen in the graph of FIG. 2, a disadvantage in a static test process may be that the testing boundaries do not change or conform to variations in local distributions of devices in a production lot. In other words, testing boundaries 210, 215 will remain fixed for the entire lot. Therefore, all devices in a production lot corresponding to data points 205 may meet the device specifications even though some of the devices may be outlier devices relative to a local distribution of a subset of devices in the production lot. Application of a post-electrical test such as Adaptive Limits may result in a narrower set of fixed or static test limits that may remove some outlier devices, but not all outlier devices would be captured using this type of test. A static test process is therefore unable to account for and adapt to variations in the mean, upper and lower bounds, and other lot-based statistics within the lot itself.

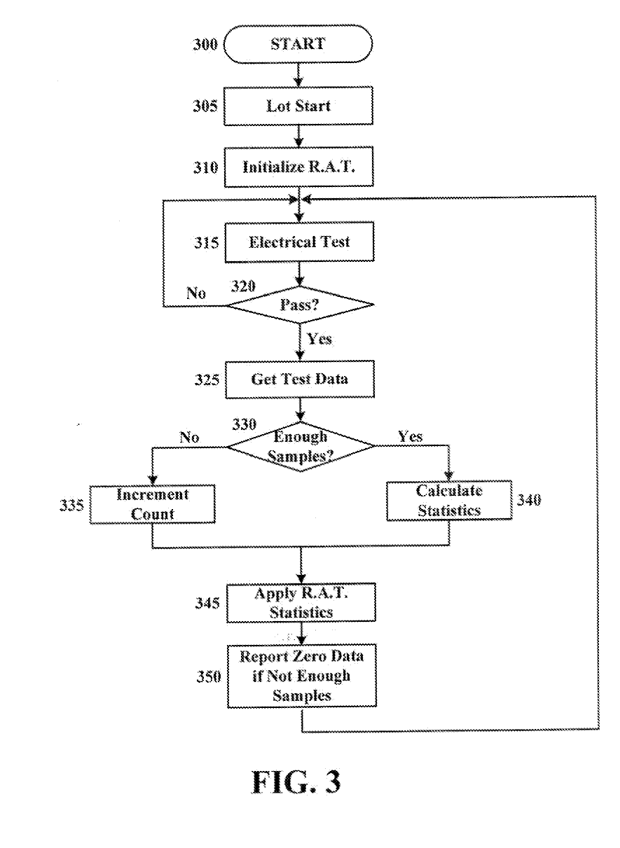

FIG. 3 illustrates in a flowchart an embodiment for implementing a dynamic in-line testing algorithm. In block 305, a production lot may be chosen for electrical and post-electrical testing. In one embodiment, each production lot may include individual semiconductor devices, integrated circuits, or dies located on a wafer. It is contemplated that other types of electrical or electronic devices may be selected for testing as well. The starting point within the production lot for testing may be random. The order in which devices are selected for testing also may be any random pattern, or may be sequential in the order in which the devices are located on a wafer. For instance, with respect to a wafer, the order in which devices or dies are selected for testing may occur in a spoke pattern, a raster pattern, or a spiral pattern. However, testing of devices may occur after individual dies have been cut from a wafer. As a result, the dies and devices may be randomized. To the extent changing the order in which devices are tested is possible, such changes may affect the distribution statistics of the devices and whether such devices pass or fail the RAT algorithm.

In block 310, a software application running the RAT algorithm may be initialized. In the alternative, a testing device may include executable code or instructions for executing the algorithm. The blocks of the flowchart beginning at block 315 may relate to an individual device from among the devices comprising a production lot. In block 315, an electrical test or other known quality assurance test may be performed to test various aspects of a selected device's function and performance. The present application is not intended to be limiting with respect to the type and number of tests capable of being applied to devices in a production lot. During the electrical test or other test, testing data may be sampled and retained for the selected device. This data may be stored in a database or other storage device.

In block 320, if the selected device under test fails the test, the device may be removed from the lot or otherwise flagged for re-testing or removal. Devices which fail the electrical test may not advance to the RAT stage of testing. If the device under test passes the electrical test, in block 325, test data obtained from the electrical test or other previously applied tests may be retrieved or gathered for the device under test for use with the RAT algorithm. The RAT algorithm may not perform additional physical testing on a device, but rather may use testing data gathered from other tests to generate distribution statistics that are regionally precise for an in-line windowed user-definable sample. In block 330, the software application running the RAT algorithm may check to see if it has obtained enough samples to begin executing the algorithm. The RAT may require a predetermined user-selectable number of samples to be obtained before statistics may be generated. For example, the RAT algorithm may be executed after testing data from 30 devices are gathered and/or sampled. These samples may comprise a window or portion of the total number of devices in a production lot or wafer. As the devices in the production lot are cycled through during testing, the window for the RAT algorithm may move as well. In this respect, each device being tested using the RAT algorithm may be compared against a regional distribution of devices rather than the entire production lot.

If the minimum threshold for beginning execution of the RAT algorithm has not been met, the application may increment a counter in block 335. The counter may track the number of devices for which testing data has been received. If enough samples have been obtained from devices in a production lot, the rolling average test algorithm may calculate statistics for the obtained samples, including the mean of the samples and the standard deviation or sigma, as shown in block 340.

In block 345, the RAT statistics may be applied to determine which devices meet programmable requirements relative to the window of samples to which the devices are compared against. The RAT algorithm is programmable, such that a user can determine to what degree of precision a device must meet, as expressed in one embodiment in terms of standard deviations from the mean. For example, a user may define the acceptability of a device to be within three standard deviations of the mean. Those devices having test data outside of three standard deviations from the mean may be considered outlier devices, while other devices within three standard deviations from the mean are acceptable. How precise each device must be may differ for different applications. For example, devices used in automotive applications may be less precise than devices used in medical application. The programmable nature of the RAT algorithm enables the testing of devices to be customized. For the case where not enough testing data from devices has been obtained, in block 350, the algorithm may report that not enough data has been gathered for the algorithm to properly execute. The process may return to block 315 and apply an electrical or other test on the next device in the production lot. Blocks 315 through 350 may iteratively repeat until all semiconductor devices in a production lot have been selected and tested using the algorithm.

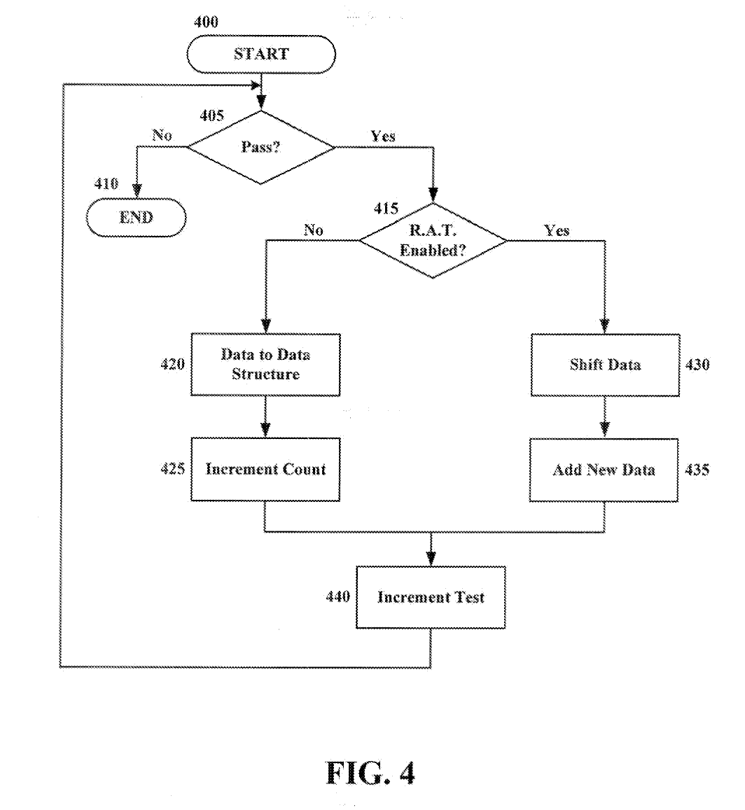

FIG. 4 illustrates in a flowchart an embodiment for implementing a dynamic in-line testing algorithm. The RAT algorithm may operate on test data previously obtained for devices in a production lot or dies on a wafer. The RAT algorithm may test a portion of the total number of devices or dies and change the portion of the lot being tested as the algorithm progresses through the devices making up the lot. A software application implementing the RAT algorithm may run multiple tests on test data corresponding to the devices under test. The number of tests to be run, the number of devices to be tested, and the precision of the testing (e.g., acceptable standard deviations from the mean) are programmable within the software application.

In block 405, for each device, the device is first checked to determine whether it passes an electrical test. Other tests may be substituted in place of the electrical test. If the device fails the electrical test, the device is discarded and not used in the RAT algorithm, as the failed test may indicate the device does not function properly. If the device passes the test, a software application or a device running the RAT algorithm may verify if the RAT algorithm is enabled. The RAT algorithm may be enabled if test data from a predetermined, user-selectable number of devices has been gathered. If the RAT algorithm has not been enabled, test data for the specific device is stored, as shown in block 420. In one embodiment, the test data may be stored in an array, although other types of data structures, such as queues and linked lists, may be implemented and used. A counter may be incremented in block 425. The counter may track the number of devices from which test data has been gathered in order to determine whether the number of devices for which the application has testing data meets the predetermined threshold number of devices needed to enable the RAT algorithm.

In block 430, if the RAT algorithm has been enabled, data corresponding to the oldest or earliest selected device stored into the data structure may be shifted out of or evicted from the data structure. The data structure may store test data for n devices, with n corresponding to the predetermined, user-selected sample size, and with the earliest input device occupying, for instance, the nth spot in the data structure, and the most recently input device occupying, for instance, the first spot in the data structure. Test data corresponding to each other device in the data structure also may shift one location in the data structure to indicate that each device and its test data are now one device less recent. In this respect, as devices are selected, the data structure may hold test data corresponding to the n most recently selected devices, with n being less than the total number of devices in the production lot. Thus, the RAT algorithm is able to capture and account for regional variations in the devices occur as devices are selected from the production lot. In block 435, test data corresponding to the latest device tested is shifted into the data structure to occupy the data location corresponding to the most recently input device. In block 440, since a software application implementing the RAT algorithm may run multiple tests, the test number may be incremented.

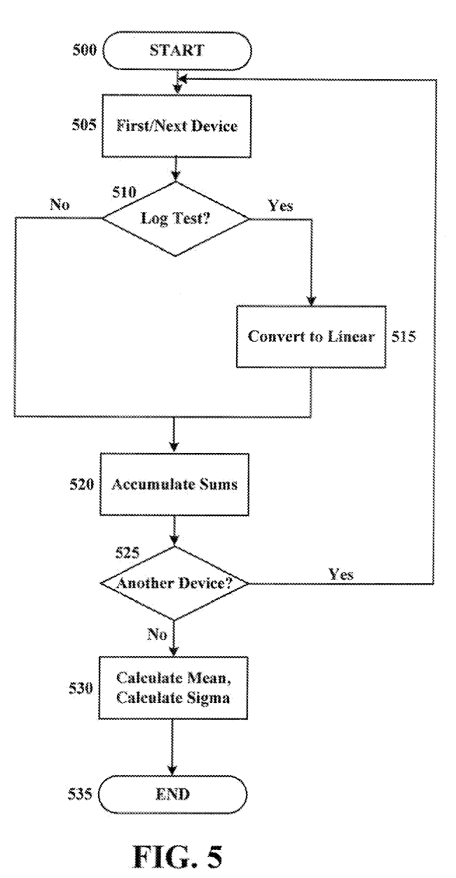

FIG. 5 illustrates in a flowchart an embodiment for implementing a dynamic in-line testing algorithm. In block 505, a first or next device may be selected for inclusion in the rolling average test. In block 510, testing data associated with the device is checked to verify whether the test data has a logarithmic distribution. Test data having a logarithmic distribution may exhibit a skewed distribution. In order to compile and use the various test results, the test results may be expressed in the same scale. If the test results are logarithmically distributed, in block 515, the results are converted into a Gaussian distribution by virtue of a linear transformation, thereby allowing valid application of statistical methods.

In block 520, test results from the various devices are accumulated and totaled. In block 525, if test results from another device are to be added, the process returns to block 505 to add the results from another device. If another device is not to be added, in block 530, the mean and standard deviation or sigma may be calculated from the sum of the test results of the window of devices. The mean and sigma may be re-calculated each time a new device is added to and an old device is removed from the window of samples. In this respect, the mean and sigma will reflect only those devices of the production lot that are a part of the window of n devices, with n being a predetermined, user-defined number. Unlike a static test that does not account for regional variations in manufacturing processes for a production lot, this dynamic in-line testing scheme may identify and reject variations in manufacturing processes through the use of a window of devices that moves through the production lot.

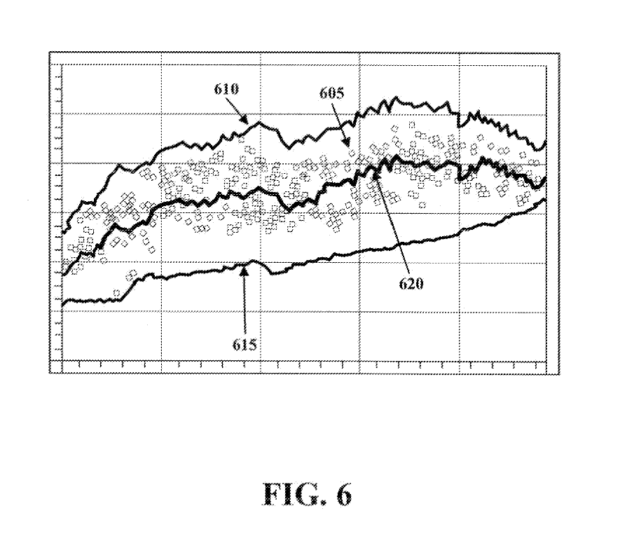

FIG. 6 illustrates a graph of an embodiment of a dynamic in-line testing algorithm. In FIG. 6, raw data points 605 may illustrate test results corresponding to various devices from a production lot. The RAT algorithm may calculate a mean 620 and sigma from the raw data points 605. The mean 620 may vary as new devices are input into the RAT algorithm and old devices are removed from the RAT algorithm. The changing mean may reflect process variations that occur regionally in a production lot. The sigma may be used to determine an upper bound 610 and a lower bound 615 for the devices being tested. The user may define how many standard deviations from the mean may be acceptable for the devices being tested. Devices located above the upper bound 610 and below the lower bound 615 may be considered as outliers. Outliers may be otherwise functioning devices that vary beyond acceptable limits relative to other devices located in the same region or neighborhood of the production lot as the outlier devices. Outliers may be flagged during testing and later removed or re-tested.

Several features and aspects of the present invention have been illustrated and described in detail with reference to particular embodiments by way of example only, and not by way of limitation. Those of skill in the art will appreciate that alternative implementations and various modifications to the disclosed embodiments are within the scope and contemplation of the present disclosure. For example, the foregoing embodiments have been described with reference to devices, semiconductor devices, and integrated circuits. It will be apparent to one skilled in the art that the RAT algorithm may apply to any electronic device or component. Further, the statistics generated by the RAT algorithm may be used to analyze the devices in a production lot in additional ways. The statistics may identify or indicate sudden, large shifts in the mean of a sample of devices. This and other uses of the statistics may allow for additional testing and verification to be performed on the devices in a production lot. Therefore, it is intended that the invention be considered as limited only by the scope of the appended claims.

What is claimed is:

1. A method of performing dynamic in-line testing of semiconductor devices, comprising:
sequentially testing a plurality of semiconductor devices;
storing test data for a predetermined number of semiconductor devices of the sequentially tested semiconductor devices in a data structure;
thereafter, iteratively, until completion of the method:
calculating statistics for the predetermined number of semiconductor devices using the stored test data;
if test data associated with a device of the predetermined number of semiconductor devices exceeds a precision setting based on the calculated statistics, marking the device as an outlier;
evicting, from the data structure, test data corresponding to an earliest tested semiconductor device in sequence; and
storing, in the data structure, test data of a next tested semiconductor device in sequence.

2. The method of claim 1, further comprising responsive to said sequentially testing, incrementing a counter when a number of semiconductors devices whose test data is stored in the data structure is less than the predetermined number.

3. The method of claim 1, wherein said sequentially testing comprises sequentially performing an electrical test on the plurality of semiconductor devices.

4. The method of claim 1, wherein a first sequentially tested semiconductor device is randomly selected from among the plurality of semiconductor devices.

5. The method of claim 1, wherein the data structure is selected from the group consisting of an array, a queue, and a linked list.

6. The method of claim 1, wherein the statistics include a mean and a standard deviation of the stored test data.

7. The method of claim 6, wherein the precision setting is defined as a function of the standard deviation.

8. The method of claim 1, further comprising discarding the outlier device from the plurality of semiconductor devices.

9. The method of claim 1, further comprising, if the stored test data has a logarithmic distribution, converting the stored test data to a Gaussian distribution.

10. A computer-readable storage medium storing a set of instructions that when executed causes a processor to implement a method, comprising:
sequentially testing a plurality of semiconductor devices;
storing test data for a predetermined number of semiconductor devices of the sequentially tested semiconductor devices in a data structure;
thereafter, iteratively, until completion of the method:
calculating statistics for the predetermined number of semiconductor devices using the stored test data;
if test data associated with a device of the predetermined number of semiconductor devices exceeds a precision setting based on the calculated statistics, marking the device as an outlier;
evicting, from the data structure, test data corresponding to an earliest tested semiconductor device in sequence; and
storing, in the data structure, test data of a next tested semiconductor device in sequence.

11. The computer-readable storage medium of claim 10, further comprising responsive to said sequentially testing, incrementing a counter when a number of semiconductors devices whose test data is stored in the data structure is less than the predetermined number.

12. The computer-readable storage medium of claim 10, wherein said sequentially testing comprises sequentially performing an electrical test on the plurality of semiconductor devices.

13. The computer-readable storage medium of claim 10, wherein a first sequentially tested semiconductor device is randomly selected from among the plurality of semiconductor devices.

14. The computer-readable storage medium of claim 10, wherein the data structure is selected from the group consisting of an array, a queue, and a linked list.

15. The computer-readable storage medium of claim 10, wherein the statistics include a mean and a standard deviation of the stored test data.

16. The computer-readable storage medium of claim 15, wherein the precision setting is defined as a function of the standard deviation.

17. The computer-readable storage medium of claim 10, further comprising discarding the outlier device from the plurality of semiconductor devices.

18. The computer-readable storage medium of claim 10, further comprising, if the stored test data has a logarithmic distribution, converting the stored test data to a Gaussian distribution.

19. A system for performing dynamic in-line testing of semiconductor devices, comprising:
a processor;
a database to store test data for a plurality of semiconductor devices; and
a memory, coupled to the processor, storing instructions adapted to be executed by the processor to:
sequentially test a plurality of semiconductor devices;
store test data for a predetermined number of semiconductor devices of the sequentially tested semiconductor devices in a data structure;
thereafter, iteratively, until completion of the method:
calculate statistics for the predetermined number of semiconductor devices using the stored test data;
if test data associated with a device of the predetermined number of semiconductor devices exceeds a precision setting based on the calculated statistics, mark the device as an outlier;
evict, from the data structure, test data corresponding to an earliest tested semiconductor device in sequence; and
store, in the data structure, test data of a next tested semiconductor device in sequence.

20. The system of claim 19, further comprising, responsive to said sequentially select, increment a counter when a number of semiconductors devices whose test data is stored in the data structure is less than the predetermined number.

21. The system of claim 19, wherein said sequentially test comprises sequentially performing an electrical test on the plurality of semiconductor devices.

22. The system of claim 19, wherein a first sequentially tested semiconductor device is randomly selected from among the plurality of semiconductor devices.

23. The system of claim 19, wherein the data structure is selected from the group consisting of an array, a queue, and a linked list.

24. The system of claim 19, wherein the statistics include a mean and a standard deviation of the stored test data.

25. The system of claim 24, wherein the precision setting is defined as a function of the standard deviation.

26. The system of claim 19, further comprising discarding the outlier device from the plurality of semiconductor devices.

27. The system of claim 19, further comprising, if the stored test data has a logarithmic distribution, converting the stored test data to a Gaussian distribution.
